(19) United States
(12) Patent Application Publication
(10) Pub. No.: US 2019/0041685 A1
(43) Pub. Date: Feb. 7, 2019

(54) SEMICONDUCTOR DEVICE AND DISPLAY DEVICE

(71) Applicant: SHARP KABUSHIKI KAISHA, Sakai City, Osaka (JP)

(72) Inventors: SHINZOH MURAKAMI, Sakai City (JP); YUKIO SHIMIZU, Sakai City (JP); TAKESHI HORIGUCHI, Sakai City (JP)

(73) Assignee: SHARP KABUSHIKI KAISHA, Sakai City ,Osaka (JP)

(21) Appl. No.: 16/076,998

(22) PCT Filed: Feb. 3, 2017
(86) PCT No.: PCT/JP2017/003893

§ 371 Date: Aug. 9, 2018

(30) Foreign Application Priority Data
Feb. 10, 2016 (JP) 2016-023913

(51) Int. Cl. G02F 1/1333; G02F 1/1337; H01L 27/12; G02F 1/1345; G09G 3/00

(52) U.S. Cl. CPC G02F 1/133308; G02F 1/133707; H01L 27/1218; G02F 2202/16; G09G 3/006; G02F 2201/54; G02F 1/13452

(57) ABSTRACT

The semiconductor device of the present invention includes: a first bump group including multiple first bumps aligned in a long side direction; a second bump group including multiple second bumps aligned in the long side direction; and a third bump group including multiple third bumps between the first bump group and the second bump group, wherein on the surface to be connected to the display device, in a short side direction perpendicular to the long side direction, no second bump is disposed or at least one of the multiple second bumps is disposed at least one of positions facing the multiple third bumps, the at least one of the multiple second bumps being a dummy bump.

### TECHNICAL FIELD

The present invention relates to a semiconductor device and a display device. More specifically, the present invention relates to a semiconductor device applicable to provide a narrow frame display device, and a display device.

### BACKGROUND ART

Display devices such as liquid crystal displays and organic EL displays, which are advantageously thin, light, and low in power consumption, have been widely used in electronic devices such as monitors, projectors, smartphones, tablet PCs, and personal digital assistants (PDAs). These days, display devices are increasingly becoming smaller and lighter. Along with this trend, attempts have been made to reduce the size of a peripheral area surrounding the display region, i.e., to narrow the frame.

In attempts to narrow the frame as described above, the arrangement of external connection terminals (semiconductor devices) in a display device is a key factor. As disclosed in Patent Literature 1, for example, a peripheral area surrounding a display region of a display device has a structure in which common conductive lines, an insulating film, and external connection terminals, which are used to display an image, are disposed in this order on a display panel substrate as a supporting substrate of the display device (i.e., a display panel or a substrate of the display panel), and the common conductive lines and the external connection terminals are interconnected via contact holes formed in the insulating film.

An anisotropic conductive film is disposed in a layer above the external connection terminals on the display panel substrate, and external connection components such as a flexible print circuit (hereinafter abbreviated as “FPC”) are connected to the external connection terminals via the anisotropic conductive film. When the external connection terminals and the common conductive lines are disposed to overlap each other when the display panel substrate surface is viewed from the normal direction, the area of conductive lines can be made smaller and the frame can be made narrower than when the external connection terminals and common conductive lines do not overlap each other. In addition to the above structure. Patent Literature 1 also discloses that the frame can be further narrowed by arranging the external connection terminals in parallel to the direction of the common conductive lines.

The display panel substrate and the FPC are mechanically interconnected by heating the display panel substrate and the FPC with an anisotropic conductive film disposed therebetween while pressure is applied toward the display panel substrate from a side opposite to a terminal surface of the FPC so as to cure and fix a thermosetting resin in the anisotropic conductive film. At this time, they are electrically interconnected simultaneously as metal particles in the anisotropic conductive film are sandwiched between the external connection terminals provided on the display panel substrate and FPC terminals. As in the invention disclosed in Patent Literature 1, when a high driving ability is not required for a display device, a display panel substrate may include a drive circuit formed therein.

When a high driving ability is required for a display device, a display device may be used in which a semiconductor device in the form of an integrated circuit (IC) chip having a high driving ability for driving and controlling a pixel array unit of the display panel substrate is disposed outside the display panel substrate. For example. Patent Literature 2 discloses a display device including a square-shaped semiconductor device between external connection terminals to be mounted on the FPC and a display unit of a display panel substrate, which is mounted on external connection terminals disposed on the display panel substrate via an anisotropic conductive film. This semiconductor device includes, on its surface near the anisotropic conductive film, a first bump group consisting of multiple first bumps aligned along one of mutually opposite long sides of the surface, a second bump group consisting of multiple second bumps aligned along the other long side, and a dummy bump group consisting of multiple dummy bumps aligned between the first bump group and the second bump group and in the same direction as the extension direction of the long sides.

The substrate and the semiconductor device are mechanically interconnected by heating the substrate and the semiconductor with the anisotropic conductive film disposed therebetween while pressure is applied toward the substrate from the side opposite to the bump side (side where the bumps are disposed) of the semiconductor device so as to cure and fix a thermosetting resin in the anisotropic conductive film. At this time, they are electrically interconnected simultaneously as metal particles in the anisotropic conductive film are sandwiched between the external connection terminals provided on the substrate and the bumps of the semiconductor device.

### CITATION LIST

### Patent Literature

Patent Literature 1: JP 3850510 B

Patent Literature 2: JP 2012-227480 A

### SUMMARY OF INVENTION

### Technical Problem

The semiconductor device of the display device disclosed in Patent Literature 2 at least includes the first bump group and the second bump group aligned in the extension direction of the two long sides of the semiconductor device, and the dummy bump group aligned between these bump groups. The dummy bump group includes at least one row of dummy bumps in the extension direction of the two long sides. During pressure bonding of the semiconductor device to the display panel substrate, the semiconductor device is easily separated or floated from the display panel substrate due to stress resulting from warpage of the semiconductor device. The dummy bump group is provided in order to prevent defects such as open circuit in electric connection between the bumps of the semiconductor device and the external connection terminal on the substrate or an increase in connection resistance during open circuit.

Yet, as stated in Patent Literature 2, when the dummy bump group of the semiconductor device is disposed between the first bump group and the second bump group, circuits and conductive lines to be disposed on the display panel substrate cannot be disposed between first external connection terminals and second external connection terminals on the display panel substrate below the semiconductor device, the first external connection terminals corresponding to the first bump group, and the second external connection terminals corresponding to the second bump group. This makes it difficult to narrow the frame.

The present invention is made in view of the current situation described above, and aims to provide a narrow frame display device including a third bump group between a first bump group and a second bump group of a semiconductor device, the third bump group being configured to prevent defects due to warpage of the semiconductor device or perform other functions.

### Solution to Problem

The present inventors focused on a display device including a semiconductor device on which a third bump group is disposed between a first bump group and a second bump group, the third bump group being configured to prevent defects due to warpage of the semiconductor device or perform other functions, and conducted various studies on methods for narrowing the frame of the display device. As a result, the present inventors designed a circuit board in which no second bump is disposed or at least one second bump is disposed at each of positions facing multiple third bumps in a direction perpendicular to an alignment direction of the multiple first bumps on a substrate, the at least one second bump being a dummy bump. In this manner, the above problems were successfully solved, and the present invention was thus completed.

Specifically, in one aspect, the present invention may provide a semiconductor device intended to be mounted on a display device, the semiconductor device including, on a surface to be connected to the display device: a first bump group including multiple first bumps aligned near one of long sides in a long side direction; a second bump group including multiple second bumps aligned near the other long side in the long side direction; and a third bump group including multiple third bumps between the first bump group and the second bump group, wherein on the surface to be connected to the display device, in a short side direction perpendicular to the long side direction, no second bump is disposed or at least one of the multiple second bumps is disposed at least one of positions facing the multiple third bumps, the at least one of the multiple second bumps being a dummy bump.

The “other long side” is a side facing “one of long side”. The “surface to be connected to the display device” is a main surface of the semiconductor device which is used to be electrically and mechanically connected to the display device when the semiconductor device of the present invention is mounted on the display device.

In another aspect, the present invention may provide a display device including the semiconductor device of the present invention and a display panel substrate connected to the semiconductor device via a conductive film, wherein a circuit or a conductive line is disposed in a region that overlaps a region between adjacent third bumps of the semiconductor device, on the display panel substrate.

The present invention is different from the invention disclosed in Patent Literature 2 as described below.

Patent Literature 2 is silent about positions of the output signal bumps. Patent Literature 2 shows in the drawings that the output signal bumps are aligned at equal intervals, and nowhere discloses that the output signal bumps are not disposed or dummy bumps arranged between output signal bumps are disposed at positions where warpage prevention bumps are facing in a direction perpendicular to an alignment direction of the warpage prevention bumps.

### Advantageous Effects of Invention

The present invention provides a narrow frame display device including a third bump group between a first bump group and a second bump group of a semiconductor device, the third bump group being configured to prevent defects due to warpage of the semiconductor device or perform other functions.

### BRIEF DESCRIPTION OF DRAWINGS

FIG. 1 shows a schematic plan view and a schematic side view of a structure of a display device according to Embodiment 1.

FIG. 2 shows a cross-sectional view of cross-sectional view of an a1-a2 portion shown in FIG. 1.

FIG. 3 shows a schematic block diagram of the arrangement on a display panel substrate according to Embodiment 1.

FIG. 4 shows a schematic plan view of the arrangement of bumps on a semiconductor device according to Embodiment 1.

FIG. 5 shows an enlarged view of FIG. 4.

FIG. 6 further shows a positional relationship between a conductive line layout, on the display panel substrate and the semiconductor device shown in FIG. 5 mounted on the display panel substrate.

FIG. 7 shows a schematic plan view of arrangement of bumps on a semiconductor device according to Embodiment 2.

FIG. 8 shows an enlarged view of FIG. 7.

FIG. 9 further shows a positional relationship between a conductive line layout on the display panel substrate and the semiconductor device shown in FIG. 3 mounted on the display panel substrate.

FIG. 10 shows a schematic plan view of the arrangement of bumps on a semiconductor device according to Embodiment 3.

FIG. 11 shows an enlarged view of FIG. 10.

FIG. 12 further shows a positional relationship between a conductive line layout on the display panel substrate and the semiconductor device shown in FIG. 11 mounted on the display panel substrate.

FIG. 13 shows a schematic plan block diagram of the arrangement on a display panel substrate according to Comparative Embodiment 1.

FIG. 14 shows a schematic plan view of the arrangement of bumps on a semiconductor device according to Comparative Embodiment 1.

FIG. 15 further shows a positional relationship between a conductive line layout on the display panel substrate and the semiconductor device shown in FIG. 14 mounted on the display panel substrate.

### DESCRIPTION OF EMBODIMENTS

The present invention is described in more detail below by describing embodiments with reference to drawings, but the present invention is not limited to these embodiments. Features in these embodiments may be suitably combined or modified without departing from the gist of the present invention.

The “dummy bump” as used herein is a conductor in a floating state (a state of not being electrically connected to other conductors). Bumps other than the dummy bumps are conductors electrically connected to other bumps, circuits, and conductive lines in the semiconductor device. Materials of these bumps are not particularly limited, and elemental metals such as copper (Cu) and gold (Au) and alloys including these metals can be suitably used. The semiconductor device usually refers to a substrate in the form of a driving IC chip. The substrate includes a silicon substrate as the base and circuits made of aluminum (AI), gold (Au), or the like incorporated thereinto. The bumps are formed on the surface of the substrate.

The “long side direction” as used herein means a long side direction of the surface of the semiconductor device which is to be connected to the display device. The “short side direction” as used herein means a short side direction of the surface of the semiconductor device which is to be connected to the display device. The surface of the semiconductor device which is to be connected to the display device usually has a rectangular or square shape, but the shape does not have to be strictly rectangular or square. It suffices as long as the surface is substantially rectangular or substantially square.

### Embodiment 1

Embodiment 1 is described, taking a liquid crystal panel as an example.

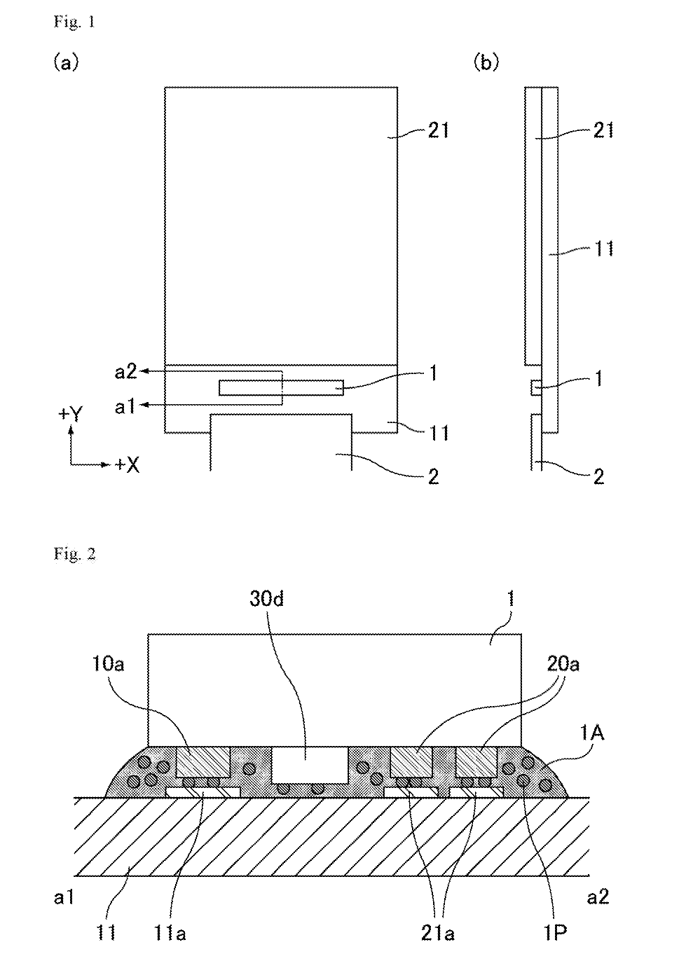

FIG. 1 shows a schematic plan view and a schematic side view of a structure of a display device according to Embodiment 1. FIG. 1 shows the arrangement of a display panel substrate, a chip-like semiconductor device 1 mounted on the display panel substrate, and an FPC board 2 mounted on the display panel substrate, of a display device according to Embodiment 1. The left in FIG. 1 is a top plan view of a surface of the semiconductor device to be connected to the FPC. The right in FIG. 1 is a side view.

A display panel substrate includes a thin film transistor (TFT) substrate 11, a color filter substrate 21, and a liquid crystal layer (not shown) therebetween. The TFT substrate 11 includes a glass substrate as a supporting substrate on which components such as multiple thin-film transistors, terminals for mounting the external semiconductor device 1 configured to drive these transistors and the FPC board 2, and circuits and conductive lines for interconnecting the thin-film transistors and the terminals are disposed. As described above, the display panel substrate according to Embodiment 1 includes a region for mounting the external semiconductor device 1 and the FPC 2. In this embodiment, these components are disposed in a region extending in a short side direction of the semiconductor device 1 (−Y direction) from the color filter substrate 21.

A backlight is disposed on the back side of the TFT substrate 11 and components such as a glass cover and a touch panel film are mounted on the front side of the color filter substrate 21 to provide a display device, but these components are not directly related to the present invention, and descriptions thereof are thus omitted.

FIG. 2 shows a cross-sectional view of cross-sectional view of an a1-a2 portion shown in FIG. 1. Specifically, FIG. 2 shows an expanded cross-sectional view of the a1-a2 portion of the semiconductor device 1 mounted on the TFT substrate 11 of the display panel substrate according to Embodiment 1.

The semiconductor device 1 includes, on its bottom, multiple conductive bumps (for example, bumps made of gold (Au)) to be electrically connected to the terminals or the like on the TFT substrate 11. The bumps include three types of bumps: output signal bumps 20a for output signals (output signals from the semiconductor device 1), input signal bumps 10a for input signals (input signals into the semiconductor device 1), and warpage prevention bumps 30d.

The TFT substrate 11 includes external connection terminals such as output signal terminals 21a formed at positions corresponding to the output signal bumps 20a of the semiconductor device, and input signal terminals 11a formed at positions corresponding to the input signal bumps 10a. The input signal terminals 11a on the TFT substrate 11 are disposed near the FPC 2, and the output signal terminals 21a are disposed near the color filter substrate 21.

Further, the input signal terminals 11a on the TFT substrate 11 are connected to the input signal bumps 10a of the semiconductor device 1 via an anisotropic conductive film 1A containing multiple conductive particles 1P, and the output signal terminals 21a on the TFT substrate 11 are connected to the output signal bumps 20a of the semiconductor device 1 via the anisotropic conductive film 1A, whereby the TFT substrate 11 and the semiconductor device 1 are connected to each other.

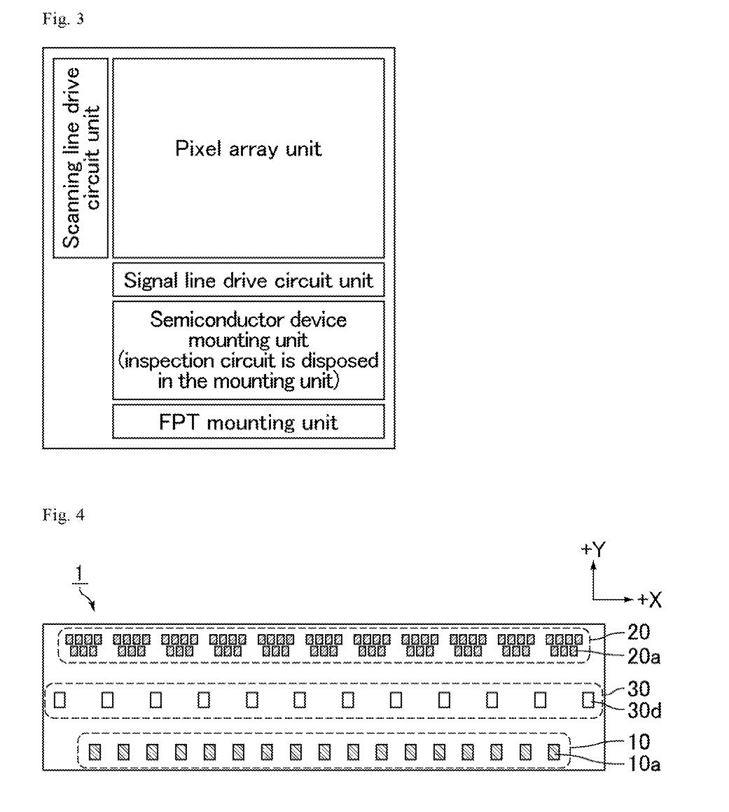

FIG. 3 shows a schematic block diagram of the arrangement on a display panel substrate according to Embodiment 1. Specifically, FIG. 3 shows a schematic block diagram of the arrangement of a pixel array unit, a scanning line drive circuit unit, a signal line drive circuit unit, a semiconductor device mounting unit, and a FPC mounting unit, which are formed on the TFT substrate of the display panel substrate according to Embodiment 1. The blocks are interconnected via conductive lines (not shown). Electrical signals inputted from outside are received by the FPC and sent to the pixel array unit through the FPC mounting unit, the semiconductor device mounting unit and the semiconductor device, and the signal line drive circuit unit to drive and control the pixel array unit. This is not directly related to the present invention, and description thereof is thus omitted. In the display panel substrate of each embodiment, as described later, a circuit such as an output line inspection circuit or conductive lines can be disposed in regions that overlap regions between adjacent third bumps, on the semiconductor device mounting unit. This makes it possible to narrow the frame of the display device.

FIG. 3 basically shows an arrangement diagram on the TFT substrate of the display panel substrate. Here, an inspection circuit is disposed in the semiconductor device. A different circuit or conductive lines may be disposed instead of the inspection circuit.

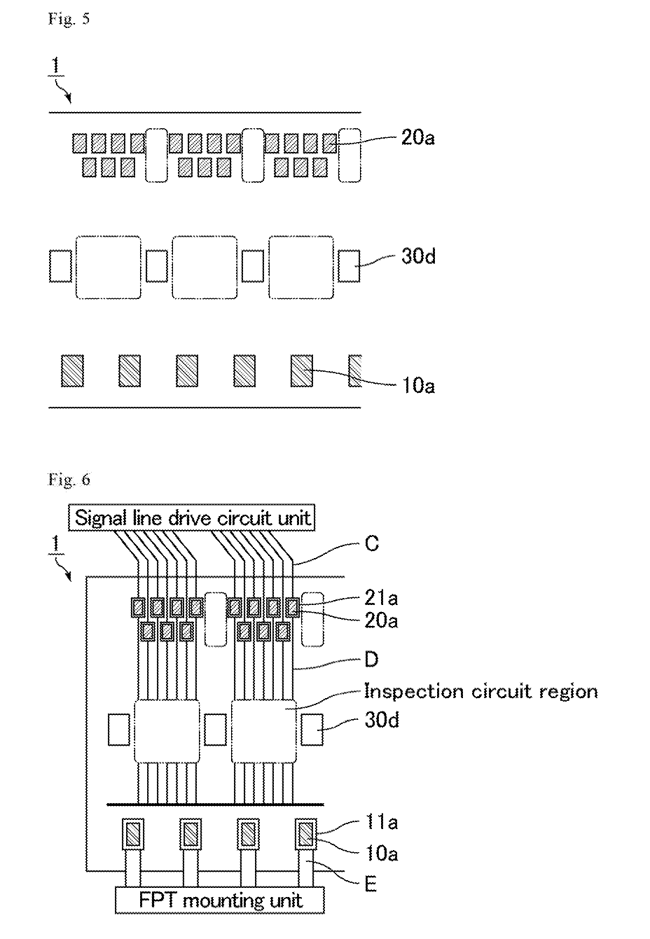

FIG. 4 shows a schematic plan view of arrangement of bumps on the semiconductor device according to Embodiment 1. FIG. 5 shows an enlarged view of FIG. 4. FIG. 6 further shows a schematic plan view of a positional relationship between a conductive line layout on the display panel substrate and the semiconductor device shown in FIG. 5 mounted on the display panel substrate. Specifically, FIG. 6 shows a plan view of a positional relationship among external connection terminals for connection to the semiconductor device 1, a layout of conductive lines extending from these terminals to predetermined blocks, and the bumps on the semiconductor device mounted on a semiconductor device mounting unit on the TFT substrate. The external connection terminal are disposed on the TFT substrate of the display panel substrate at positions corresponding to the bumps on the semiconductor device 1 having a structure shown in FIG. 5.

As shown in FIG. 4 and FIG. 5, a warpage prevention bump group 30 is disposed between an input signal bump group 10 and an output signal bump group 20. These bump groups are disposed in parallel to each other in a long side direction (X direction in FIG. 4) of the semiconductor device 1. In particular, the output signal bumps 20a are not disposed at positions facing warpage prevention bumps 30d in a direction perpendicular to the alignment direction of the warpage prevention bumps 30d (the short side direction of the semiconductor device 1 (+Y direction in FIG. 4)) on the TFT substrate of the display panel substrate. As shown in FIG. 6, an inspection circuit or the like is disposed in a region surrounded by a two-dot chain line between adjacent warpage prevention bumps 30d shown in FIG. 5 and FIG. 6, on the semiconductor device mounting unit on the TFT substrate of the display panel substrate.

The warpage prevention bumps 30d are dummy bumps, but may be functional bumps instead of the dummy bumps. The functional bumps are bumps that are not electrically floating. Examples thereof include signal bumps such as pixel output signal bumps, pixel control signal bumps, and touch panel signal bumps. When the warpage prevention bumps 30d are functional bumps, it is necessary to dispose external connection terminals at positions corresponding to the positions of the functional bumps on the TFT substrate.

Pairs of the adjacent warpage prevention bumps 30d may be disposed at equal intervals, unequal intervals, or mixed intervals (equal and unequal intervals). The warpage prevention bumps 30d may all have the same shape or different shapes, or some of them have different shapes. The warpage prevention bumps 30d are regularly aligned in one row at equal intervals, but may be aligned in two, three, or more rows, or in combination of one row and two rows.

In the direction perpendicular to the alignment direction of the warpage prevention bumps 30d (the short side direction of the semiconductor device 1 (+Y direction in FIG. 4)) on the substrate, the width of each region facing one of the warpage prevention bumps 30d where the output signal bumps 20a are not disposed (i.e., the distance between the output signal bumps 20a) does not depend on the width of each warpage prevention bump 30d in the X direction.

The input signal bumps 10a of the semiconductor device 1 are disposed such that they are electrically and mechanically connected, via the anisotropic conductive film 1A, to their corresponding input signal terminals 11a of the external connection terminals on the TFT substrate 11. Further, the output signal bumps 20a of the semiconductor device 1 are disposed such that they are electrically and mechanically connected, via the anisotropic conductive film 1A, to their corresponding output signal terminals 21a of the external connection terminals on the TFT substrate.

As shown in FIG. 2, the anisotropic conductive film 1A includes the conductive particles 1P (such as metal particles) and a resin portion. The bumps of the semiconductor device 1 are electrically connected to their corresponding external connection terminals on the TFT substrate 11 as the conductive particles 1P are sandwiched between these bumps and the terminals. The semiconductor device 1 and the TFT substrate 11 are mechanically interconnected via the resin portion of the anisotropic conductive film 1A. When the resin is a thermosetting resin, for example, the semiconductor device 1 and the TFT substrate 11 can be bonded to each other by heat pressure bonding the semiconductor device 1 to the TFT substrate 11 while pressure is applied from a side opposite to the bump side of the semiconductor device 1.

When the warpage prevention bumps 30d of the semiconductor device 1 are dummy bumps, these dummy bumps are not electrically but mechanically connected to the TFT substrate 11 via the anisotropic conductive film 1A. When the warpage prevention bumps 30d are the functional bumps, although not shown, they are disposed such that they correspond to functional signal terminals of the external connection terminals on the TFT substrate 11.

In FIG. 6, the input signal terminals 11a and the output signal terminals 21a on the TFT substrate 11 are slightly larger than the bumps (the input signal bumps 10a and the output signal bumps 20a) on the semiconductor device 1, but the size is not limited thereto, and each external connection terminal may have an area equal to or smaller than the bump area.

In FIG. 4 to FIG. 6, the output signal bumps 20a are regularly aligned at equal intervals in two rows, but they may be aligned in one row, three or more rows, or in combination of one row and two rows. Alternatively, they may be irregularly arranged. In addition, the output signal bumps 20a may be dummy bumps, pixel control signal bumps, touch panel signal bumps, or other signal bumps, instead of the output signal bumps such as pixel output signal bumps, and their functions are not limited.

In FIG. 4 to FIG. 6, the input signal bumps 10a are regularly aligned at equal intervals in one row, but they may be aligned in two, three, or more rows or in combination of one row and two rows. Alternatively, they may be irregularly arranged. The input signal bumps 10a may be dummy bumps, pixel control signal bumps, touch panel signal bumps, or other signal bumps, instead of the input signal bumps, and their functions are not limited.

In addition, in FIG. 4, the areas where the output signal bumps 20a are not disposed are periodically arranged, but the arrangement is not limited thereto, and they may be non-periodically arranged.

Further, the warpage prevention bumps 30d may not necessarily be disposed in the −Y direction of all the regions where the output signal bumps 20a are not disposed. For example, the warpage prevention bumps 30d may be disposed in the −Y direction of the regions where the output signal bumps 20a are not disposed only in the vicinity of right and left ends of the semiconductor device 1, and the warpage prevention bumps 30d may not be disposed in other regions. The warpage prevention bumps 30d may be disposed only at some regions as long as they are located at positions where the impact of warpage of the semiconductor device 1 can be reduced.

In the present invention, the structures of the input signal bump group 10, the output signal bump group 20, and the warpage prevention bump group 30 are not particularly limited as long as they fulfill the features of the present invention.

In the display device of the present invention, it is not limited to a circuit that is disposed in the regions on the TFT substrate of the display panel substrate, which overlap the regions between the warpage prevention bumps 30d. For example, only conductive lines may be disposed in these regions.

In the case of conventional structures, in the direction perpendicular to the alignment direction of the warpage prevention bumps 30d (the short side direction of the semiconductor device (+Y direction in FIG. 4)) on the substrate, the output signal bumps are disposed at positions facing the warpage prevention bumps 30d. As described in Comparative Embodiment 1, such a structure can only suppress warpage of the semiconductor device 1, and neither circuits nor conductive lines can be disposed on the regions on the display panel substrate below the semiconductor device 1. Thus, circuits such as an inspection circuit and a protection circuit need to be disposed in regions different from the regions that overlap the semiconductor device 1 on the display panel substrate, making it impossible to narrow the frame of the display panel substrate.

In Embodiment 1, in the direction perpendicular to the alignment direction of the warpage prevention bumps 30d (the short side direction of the semiconductor device 1 (+Y direction in FIG. 4)) on the substrate, the output signal bumps 20a are not disposed at positions facing the warpage prevention bumps 30d. Thus, it is possible to dispose a circuit such as an inspection circuit or conductive lines in the regions on the TFT substrate underneath the regions between the warpage prevention bumps 30d of the semiconductor device 1. As shown in FIG. 6, in order to inspect the performance of the pixel array unit on the substrate before the semiconductor device 1 is mounted thereon, conductive lines D extending in a direction opposite to conductive lines C extending from the output signal terminals 21a to a signal line drive circuit, and an inspection circuit upstream of the conductive lines D can be disposed without roundabout routing and also without interfering with the warpage prevention bumps 30d. This is not limited to the inspection circuit. Any other circuit or conductive lines can also be disposed without roundabout routing. This makes it possible to suppress warpage of the semiconductor device 1 and to narrow the frame owing to the reduced distance between the pixel array unit and the semiconductor device 1.

The display panel substrate may be a liquid crystal panel or an organic EL panel. The supporting substrate may be made of glass or resin, for example. As in the case of Embodiment 1, the semiconductor device 1 and the FPC 2 do not necessarily extend from the color filter substrate 21 in the −Y direction. They may extend in any direction.

When the display panel substrate is a liquid crystal panel, the display panel substrate may include one substrate with a color filters and one substrate having a structure capable of controlling the pixel electrode potential by switching elements such as TFTs, as in the case of conventional liquid crystal panels. The display panel substrate may include one substrate without color filters and one substrate having a structure capable of controlling the pixel electrode potential by switching elements as well as color filters.

### Embodiment 2

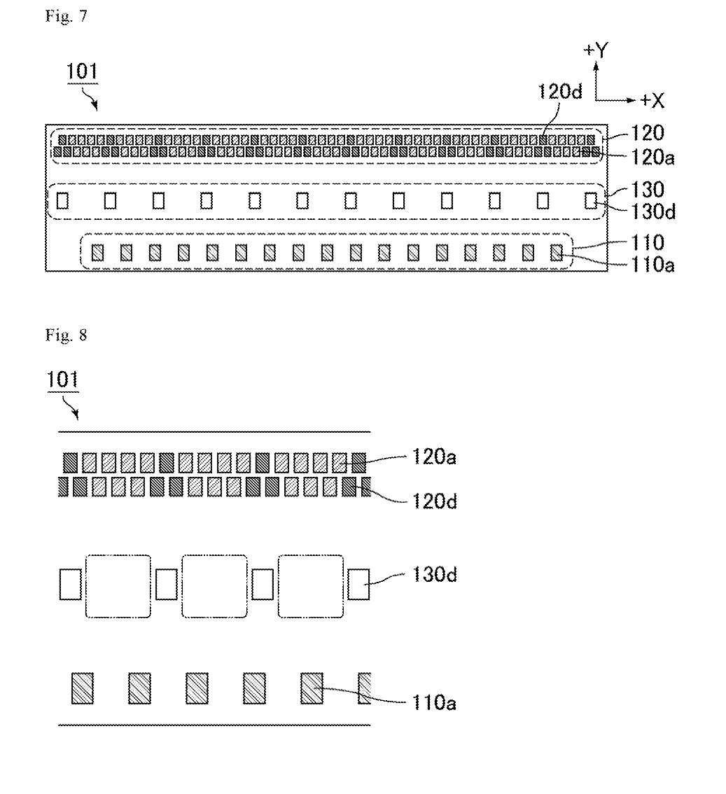

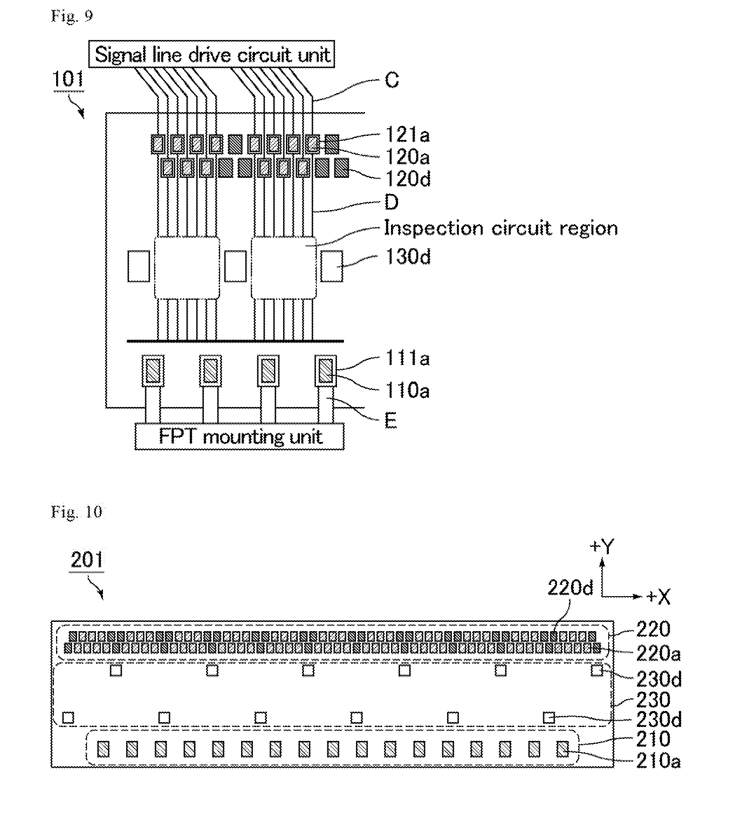

FIG. 7 shows a schematic plan view of arrangement of bumps on a semiconductor device 101 according to Embodiment 2. FIG. 8 shows an enlarged view of FIG. 7. FIG. 9 further shows a positional relationship between a conductive line layout on the display panel substrate and the semiconductor device shown in FIG. 8 mounted on the display panel substrate.

A warpage prevention bump group 130 is disposed between an input signal bump group 110 and an output signal bump group 120.

In Embodiment 2, at least one of dummy bumps 120d (shown in black) is disposed in a region between sets of multiple output signal bumps 120a in the output signal bump group 120. In particular, in a direction perpendicular to the alignment direction of warpage prevention bumps 130d (the short side direction of the semiconductor device 101 (+Y direction in FIG. 7)) on the substrate, the dummy bumps 120d are disposed at positions facing the warpage prevention bumps 130d.

The multiple dummy bumps 120d in the output signal bump group 120 may be disposed at equal intervals, unequal intervals, or mixed intervals (equal and unequal intervals). The multiple dummy bumps 120d may all have the same shape or different shapes, or some of them have different shapes.

Other structures of the device according to Embodiment 2 are the same as those described for Embodiment 1.

In Embodiment 2, while warpage of the semiconductor device 101 is suppressed by disposing the warpage prevention bumps 130d, a circuit such as an inspection circuit or conductive lines can be disposed in the regions on the TFT substrate underneath the regions between the warpage prevention bumps 130d of the semiconductor device 101. As shown in FIG. 9, the conductive lines D extending in a direction opposite to the conductive lines C extending from the output signal terminals 121a to a signal line drive circuit, and an inspection circuit upstream of the conductive lines D can be disposed without roundabout routing and also without interfering with the warpage prevention bumps 130d. This is not limited to the inspection circuit. Any other circuit or conductive lines can also be disposed without roundabout routing. Thus, the distance between the pixel array unit and the semiconductor device 101 can be reduced, and the frame can be further narrowed.

### Embodiment 3

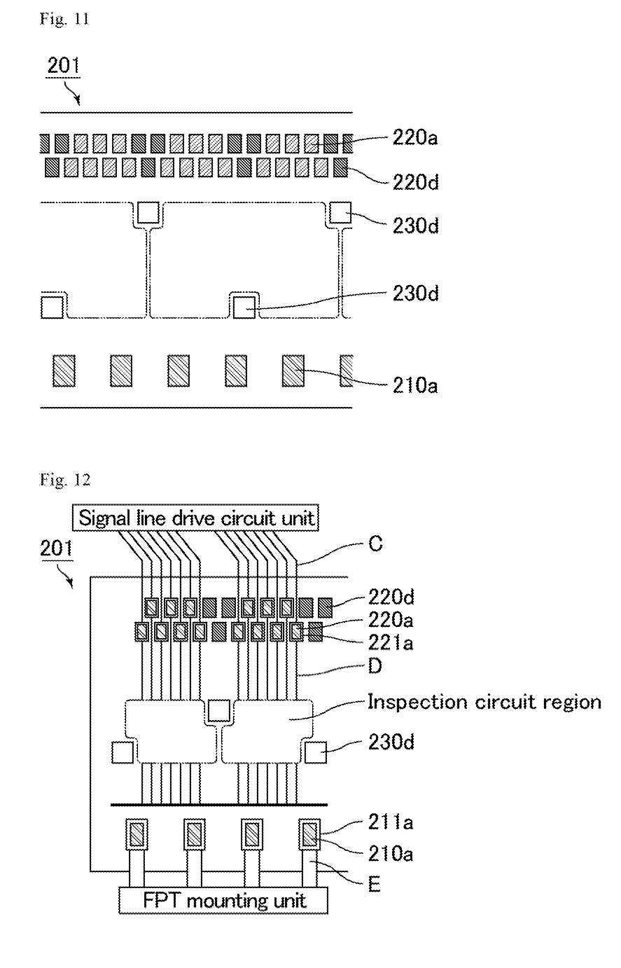

FIG. 10 shows a schematic plan view of the arrangement of bumps on a semiconductor device 201 according to Embodiment 3. FIG. 11 shows an enlarged view of FIG. 10. FIG. 12 further shows a positional relationship between a conductive line layout on the display panel substrate and the semiconductor device shown in FIG. 11 mounted on the display panel substrate.

As shown in FIG. 10 to FIG. 12, multiple warpage prevention bumps 230d are disposed in a staggered arrangement in a warpage prevention bump group 230 between an input signal bump group 210 and an output signal bump group 220.

In Embodiment 3, one or more dummy bumps 220d (shown in black) are disposed in a region between sets of multiple output signal bumps 220a in the output signal bump group 220. In particular, in a direction perpendicular to the alignment direction of the warpage prevention bumps 230d in two rows (the short side direction of the semiconductor device 201 (+Y direction in FIG. 10)) on the substrate, at least one of the dummy bumps 220d is disposed at a position facing one of the warpage prevention bumps 230d.

The multiple dummy bumps 220d in the output signal bump group 220 may be disposed at equal intervals, unequal intervals, or at mixed intervals (equal and irregular intervals). The multiple dummy bumps 220d may all have the same shape or different shapes, or some of them have different shapes.

The warpage prevention bumps 230d are dummy bumps, but may be functional bumps instead of the dummy bumps. The functional bumps may be pixel output signal bumps, pixel control signal bumps, touch panel signal bumps, or other signal bumps, and their functions are not limited.

The arrangement of the warpage prevention bumps and the functional bumps are not limited to the staggered arrangement, and these bumps may be randomly disposed as long as they can prevent warpage or perform other functions.

Other structures of the device according to Embodiment 3 are the same as those described for Embodiment 1.

In Embodiment 3, while warpage of the semiconductor device 201 is suppressed by disposing the warpage prevention bumps 230d in a staggered arrangement, a circuit such as an inspection circuit or conductive lines can be disposed in the regions on the TFT substrate underneath the regions between the warpage prevention bumps 230d of the semiconductor device 201. As shown in FIG. 12, the conductive lines D extending in a direction opposite to the conductive lines C extending from output signal terminals 221a to the signal line drive circuit, and an inspection circuit upstream of the conductive lines D can be disposed without roundabout routing and also without interfering with the warpage prevention bumps 230d. This is not limited to the inspection circuit. Any other circuit or conductive lines can also be disposed without roundabout routing. In particular, since the warpage prevention bumps 230d are disposed in a staggered arrangement, it is possible to enlarge a region where a circuit can be disposed below the semiconductor device 201, and to increase the width of a circuit and the width of a conductive line to be disposed therein. Thus, the distance between the pixel array unit and the semiconductor device 201 can be reduced, and the frame can be further narrowed.

### Comparative Embodiment 1

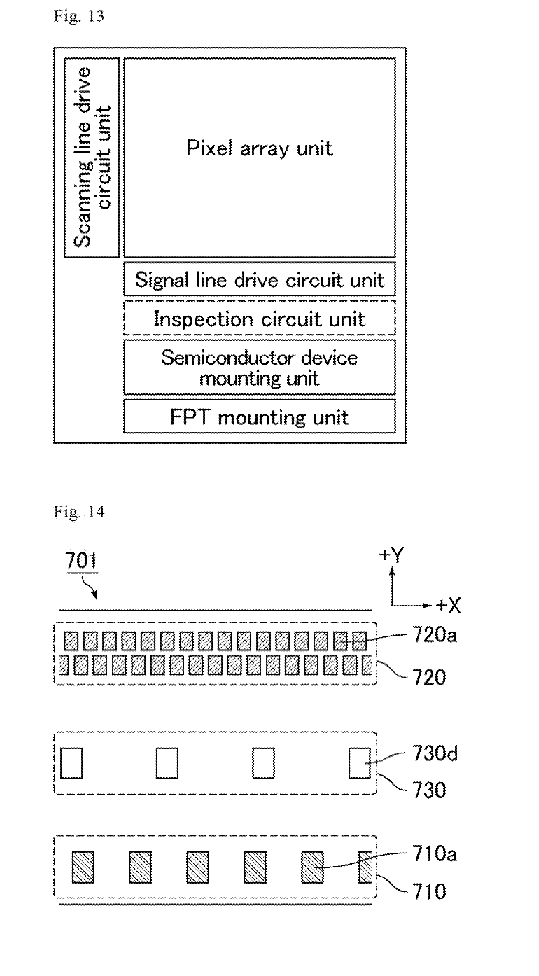

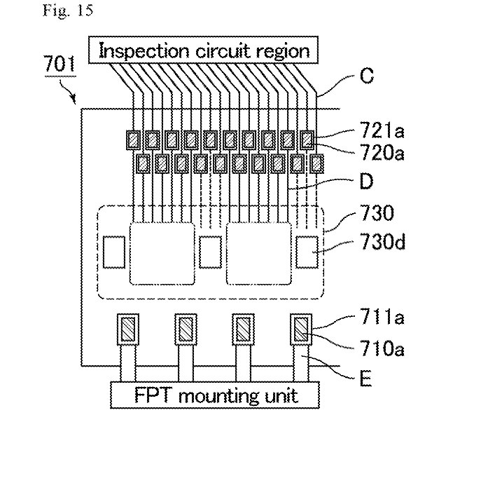

FIG. 13 shows a schematic plan block diagram of the arrangement on a display panel substrate according to Comparative Embodiment 1. Specifically, FIG. 13 shows a schematic plan block diagram of the arrangement of a pixel array unit, a scanning line drive circuit unit, a signal line drive circuit unit, an inspection circuit unit, a semiconductor device mounting unit, and an FPC mounting unit, which are formed on the TFT substrate of the display panel substrate according to Comparative Embodiment 1. The blocks are interconnected via conductive lines (not shown). Electrical signals inputted from outside are received by the FPC and sent to the pixel array unit through the FPC mounting unit, the semiconductor device mounting unit and the semiconductor device, the inspection circuit unit, and the signal line drive circuit unit to drive and control the pixel array unit. FIG. 14 shows a schematic plan view of the arrangement of bumps on a semiconductor device 701 according to Comparative Embodiment 1. FIG. 15 further shows a plan view of a positional relationship among external connection terminals, a layout of conductive lines extending from these terminals to predetermined blocks, and the bumps on the semiconductor device 701 mounted on the semiconductor device mounting unit on the TFT substrate. The external connection terminals are disposed on the TFT substrate at positions corresponding to the bumps on the semiconductor device 701 arranged on a display panel shown in FIG. 14. In the display panel substrate according to Comparative Embodiment 1, as described later, an inspection circuit or the like cannot be disposed in regions on the TFT substrate underneath the regions between adjacent warpage prevention bumps 730d of the semiconductor device 701. This makes it impossible to narrow the frame of the display device.

FIG. 13 basically shows a block diagram of the arrangement on the TFT substrate of the display panel. The semiconductor device mounting unit is electrically and mechanically connected to the semiconductor device via an anisotropic conductive film, and other components such as a pixel array unit, a scanning line drive circuit unit, a signal line drive circuit unit, an inspection circuit unit, and the FPC mounting unit are all disposed on the TFT substrate of the display panel substrate.

In the display panel substrate according to Comparative Embodiment 1, circuits such as a scanning line drive circuit unit, a signal line drive circuit unit, an inspection circuit unit, and a protection circuit unit (not shown) are located outside the semiconductor device mounting unit. An examination was carried out to determine whether or not one of the circuits can be disposed between input signal bumps and output signal bumps of the semiconductor device 701.

Here, the semiconductor device 701 according to Comparative Embodiment 1 includes not only input signal bumps 710a and output signal bumps 720a but also the warpage prevention bumps 730d. Because of the warpage prevention bumps 730d, circuits and conductive lines need to be disposed in narrow regions between the warpage prevention bumps 730d, but some conductive lines (conductive lines in dots, extending from the bumps 720a of the output signal bump group in FIG. 15) cannot be routed on the panel side. Thus, an inspection circuit or the like cannot be disposed in a region below the semiconductor device 701 (a region surrounded by a two-dot chain line) and need to be disposed outside the region. Thus, it is not possible to narrow the frame of the display panel substrate. In addition, when one of the circuits of the display panel substrate is disposed in a region below the semiconductor device 701 in order to narrow the frame, if interference occurs with the warpage prevention bumps 730d, the circuit may be electrically shorted due to particles of an anisotropic conductive film (ACF) interconnecting the semiconductor device 701 and the display panel substrate. Thus, the number of the warpage prevention bumps 730d needs to be reduced in order to prevent interference between the semiconductor device 701 and the bumps.

The above problems are due to the following factors.

(1) Since a circuit such as an inspection circuit between the semiconductor device 701 and the pixel array unit is disposed outside the semiconductor device 701, it is difficult to narrow the frame.
(2) When one of the circuits of the display panel substrate is disposed in a region below the semiconductor device 701, the circuit may be shorted to the warpage prevention bumps 730d via particles in the ACF interconnecting the semiconductor device 701 and the display panel substrate, resulting in malfunction.
(3) A thinner profile of the semiconductor device 701 more easily causes warpage of the semiconductor device 701 when the semiconductor device 701 is pressure bonded to the display panel substrate.

In the display device according to each of the above embodiments of the present invention, the third bump group that prevents defects due to warpage of the semiconductor device 701 is disposed between the first bump group and the second bump group of the semiconductor device 701, and the factor (3) above is thus eliminated. In addition, in the display device of each of the above embodiments of the present invention, no second bump is disposed or at least one of the multiple second bumps is disposed at least one of positions facing the multiple third bumps. Thus, one of the circuits of the display panel substrate can be disposed between adjacent warpage prevention bumps. As a result, a short between the circuit and the warpage prevention bumps can be sufficiently prevented, and the frame of the display panel substrate can be narrowed at the same time. Thus, the factors (1) and (2) above are eliminated.

### (Additional Remarks)

Preferred embodiments of the semiconductor device and the display device of the present invention are described below. These embodiments can be suitably combined without departing from the gist of the present invention.

In the semiconductor device of the present invention, the multiple third bumps are preferably aligned in the long side direction.

In the semiconductor device of the present invention, the multiple third bumps are preferably disposed in a staggered arrangement.

In the semiconductor device of the present invention, in the short side direction, preferably, no second bump is disposed or at least one of the multiple second bumps is disposed at each of positions facing the multiple third bumps, the at least one of the multiple second bumps being a dummy bump.

In the semiconductor device of the present invention, preferably, the first bumps are input signal bumps, and the second bumps are output signal bumps.

In the semiconductor device of the present invention, the third bumps are preferably dummy bumps.

In the semiconductor device of the present invention, the third bumps may be used to prevent warpage of the semiconductor device, or may be functional bumps such as pixel output signal bumps, controlling signal bumps, touch panel signal bumps, or signal bumps. Preferably, the third bumps are used to prevent warpage of the semiconductor device.

In the display device of the present invention, the conductive film is preferably an anisotropic conductive film. The anisotropic conductive film may be formed from, for example, a resin composition containing a resin (e.g., epoxy resin or acrylic resin) and a thermosetting reactant to which conductive fine particles (i.e., resin balls having a diameter of about 2 to 10 μm and plated with metal such as nickel (Ni), gold (Au)) are added.

In the display device of the present invention, the circuit is preferably an inspection circuit. It is also preferred that the circuit is a protection circuit. Examples of the inspection circuit and the protection circuit include an output line inspection circuit and an output line protection circuit.

### REFERENCE SIGNS LIST

1, 101, 201, 701: semiconductor device
1A: anisotropic conductive film
1P: conductive particle
2: FPC
10, 110, 210, 710: input signal bump group
10a, 110a, 210a, 710a: input signal bump
11: TFT substrate
11a, 111a, 211a, 711a: external connection terminal (input signal terminal)
20, 120, 220, 720: output signal bump group
20a, 120a, 220a, 720a: output signal bump
21: color filter substrate
21a, 121a, 221a, 721a: external connection terminal (output signal terminal)
30, 130, 230, 730: warpage prevention bump group
30d, 130d, 230d, 730d: warpage prevention bump
120d, 220d: dummy bump
C, D, E: conductive line

1. A semiconductor device intended to be mounted on a display device, the semiconductor device comprising, on a surface to be connected to the display device:
a first bump group including multiple first bumps aligned near one of long sides in a long side direction;
a second bump group including multiple second bumps aligned near the other long side in the long side direction; and
a third bump group including multiple third bumps between the first bump group and the second bump group,
wherein on the surface to be connected to the display device, in a short side direction perpendicular to the long side direction, no second bump is disposed or at least one of the multiple second bumps is disposed at least one of positions facing the multiple third bumps, the at least one of the multiple second bumps being a dummy bump.

2. The semiconductor device according to claim 1,
wherein the multiple third bumps are aligned in the long side direction.

3. The semiconductor device according to claim 1,
wherein the multiple third bumps are disposed in a staggered arrangement.

4. The semiconductor device according to claim 1,
wherein in the short side direction, no second bump is disposed or at least one of the multiple second bumps is disposed at each of positions facing the multiple third bumps, the at least one of the multiple second bumps being a dummy bump.

5. The semiconductor device according to claim 1,
wherein the first bumps are input signal bumps, and the second bumps are output signal bumps.

6. The semiconductor device according to claim 1,
wherein the third bumps are dummy bumps.

7. The semiconductor device according to claim 1,
wherein the third bumps are intended to prevent warpage of the semiconductor device.

8. A display device comprising:
the semiconductor device according to claim 1; and
a display panel substrate connected to the semiconductor device via a conductive film,
wherein a circuit or a conductive line is disposed in a region that overlaps a region between adjacent third bumps of the semiconductor device, on the display panel substrate.

9. The display device according to claim 8,
wherein the conductive film is an anisotropic conductive film.

10. The display device according to claim 8,
wherein the circuit is an inspection circuit.

11. The display device according to claim 8,
wherein the circuit is a protection circuit.
